(19) United States
(12) Patent Application Publication
(10) Pub. No.: US 2026/0251862 A1
(43) Pub. Date: Aug. 27, 2026

(54) SEMICONDUCTOR DEVICE

(71) Applicant: PanelSemi Corporation, New Taipei City (TW)

(72) Inventors: Jeng-Long SHEU, New Taipei City (TW); Chin-Tang LI, New Taipei City (TW)

(21) Appl. No.: 19/550,932

(22) Filed: Feb. 26, 2026

Related U.S. Application Data
(60) Provisional application No. 63/763,579, filed on Feb. 26, 2025.

(51) Int. Cl. G02B 6/42; H10W 90/10

(52) U.S. Cl. CPC G02B 6/4214; G02B 6/4206; G02B 6/4239; H10W 90/10

(57) ABSTRACT

A semiconductor device includes a substrate structure, a cavity arranged in the substrate structure, an integrated circuit unit arranged on the substrate structure, an optical path, and an optical coupling structure configured within the cavity. The substrate structure includes a waveguide layer, the cavity communicated with the waveguide layer, and the integrated circuit unit includes a photonic integrated circuit having an optoelectronic element corresponding to the cavity. The optical path forms between the photonic integrated circuit and the waveguide layer, and the optical coupling structure steers the optical path form a first direction to a second direction.

### CROSS REFERENCE TO RELATED APPLICATIONS

This Non-provisional application claims priority to U.S. provisional patent application with serial number 63/763,579 filed on February 26, 2025. This and all other extrinsic materials discussed herein are incorporated by reference in their entirety.

### BACKGROUND

### Technology Field

The disclosure relates to a semiconductor device, particularly to a semiconductor device for optical component packaging.

### Description of Related Art

As semiconductor devices require increasing data exchange with external devices, traditional electrical signal transmission interfaces have encountered bottlenecks, including limitations in transmission speed, electromagnetic interference issues, and high power consumption challenges. Consequently, the industry has begun adopting optical communication as an alternative solution. While optical communication offers advantages such as high transmission speed, strong interference resistance, and lower power consumption, integrating optical communication into semiconductor devices still presents numerous technical challenges. The current common practice is to place optoelectronic conversion modules separately adjacent to the semiconductor chip. Although this implementation is simple, it significantly increases the overall device size. Furthermore, the lengthy electrical connection paths required between the optoelectronic conversion modules and the semiconductor chip not only increase signal delay but are also susceptible to electromagnetic interference. Additionally, the alignment between optoelectronic conversion elements and waveguides remains a critical issue, as temperature variations and mechanical stress can cause alignment shifts that affect optical coupling efficiency. Existing technologies typically require complex alignment structures and packaging methods to maintain stability, which increases manufacturing costs. Therefore, how to maintain device miniaturization while ensuring stable optical coupling has become a crucial challenge faced by semiconductor devices integrating optical communication interfaces.

### SUMMARY

One aspect of this disclosure is to provide a semiconductor device and one or more exemplary embodiments thereof, which are used to illustrate the optical coupling between the semiconductor device and external optical signals.

This disclosure is to provide a semiconductor device that includes a substrate structure, a cavity, an integrated circuit unit, an optical path, and an optical coupling structure. The substrate structure comprises a base layer and a waveguide layer stacked on the base layer; the substrate structure defines a surface. The cavity is arranged in the substrate structure, communicates with the waveguide layer, and includes an opening on the surface of the substrate structure. The integrated circuit unit is arranged above the surface of the substrate structure and includes a photonic integrated circuit (PIC) that includes an optoelectronic element corresponding to the cavity. The optical path is formed between the optoelectronic element and the waveguide layer. The optical coupling structure is configured within the cavity to steer the optical path. The optical coupling structure includes a continuous surface, an optical reflective layer partially arranged on at least a portion of the continuous surface, and a light-transmitting window corresponding to the waveguide layer. The continuous surface and the light reflective layer are configured to guide the optical path from a first direction of the waveguide layer to a second direction.

This disclosure is to provide a semiconductor device that includes a substrate structure, a cavity, an integrated circuit unit, an optical path, and an optical coupling structure. The substrate structure comprises a base layer and a waveguide layer stacked on the base layer; the substrate structure defines a surface. The cavity is arranged in the substrate structure, communicates with the waveguide layer, and includes an opening on the surface of the substrate structure. The integrated circuit unit is arranged above the surface of the substrate structure and includes a photonic integrated circuit (PIC) that includes a light-emitting element corresponding to the cavity. The optical path is formed between the light-emitting element and the waveguide layer. The optical coupling structure is configured within the cavity to steer the optical path. The optical coupling structure includes a continuous surface, an optical reflective layer partially arranged on at least a portion of the continuous surface, and a light-transmitting window corresponding to the waveguide layer. The continuous surface and the light reflective layer are configured to guide the optical path from a first direction of the waveguide layer to a second direction.

In one embodiment, the optoelectronic element or the light-emitting element is arranged in the cavity.

In one embodiment, the waveguide layer comprises a plurality of core layers, and the wave guide layer defines a light-receiving depth, the light-receiving depth is a distance between the opening of the cavity and the one layer of the core layers; the light-emitting element defines an insertion depth which is a distance between the opening of the cavity and a free end of the light-emitting element; the light-receiving depth is greater than the insertion depth.

In one embodiment, the semiconductor device further includes a metal reflective structure surrounding the optical coupling structure, the metal reflective structure comprises a first metal reflective surface arranged on one side opposite the opening of the cavity.

In one embodiment, the light-reflective layer is the first metal reflective surface or a dielectric reflective layer.

In one embodiment, the metal reflective structure further includes a second metal reflective surface on the surface of the substrate structure.

In one embodiment, the metal reflective structure further includes a third metal reflective surface arranged on one side of the substrate structure along a direction perpendicular to the surface of the substrate structure, and the third metal reflective surface connects to the first metal reflective surface.

In one embodiment, the metal reflective structure includes a groove, an axis of the groove is parallel to the axis of the cavity; and the third metal reflective surface is arranged along one sidewall of the groove.

In one embodiment, the substrate structure defines an electrical layer on the surface.

In one embodiment, the substrate structure comprises an electrical connection structure which is arranged along a direction perpendicular to the surface of the substrate structure.

In one embodiment, the waveguide layer is arranged within the base layer and a surface thereof facing to the integrated circuit unit is flush with a surface of the base layer facing to the integrated circuit unit.

In one embodiment, the base layer includes a rigid layer and a resilient layer stacked over the rigid layer.

In one embodiment, the waveguide layer includes a polymer waveguide layer or a silicon waveguide layer.

In one embodiment, the integrated circuit unit further includes an electronic integrated circuit.

In one embodiment, the electronic integrated circuit and the photonic integrated circuit are individual from one another.

In one embodiment, the integrated circuit unit further includes a circuit substrate, and the photonic integrated circuit is arranged on the circuit substrate.

In one embodiment, the integrated circuit unit further includes a circuit substrate, and the photonic integrated circuit and the electronic integrated circuit are arranged on the circuit substrate.

In one embodiment, the cavity defines a plane with an inclined angle or a concave surface with an inclined angle, and the plane or the concave surface forms the continuous surface of the optical coupling structure.

In one embodiment, the optical coupling structure defines a concave surface toward the opening of the cavity, and the concave surface forms the continuous surface of the optical coupling structure, the optical reflective layer of the optical coupling structure is arranged on at least a partial of the continuous surface, and the light-transmitting window is defined by the continuous surface.

In one embodiment, the semiconductor device further comprises a first filling material in the cavity, the first filling material forms the concave surface toward the opening of the cavity.

In one embodiment, the first filling material comprises crystalline or amorphous silicon dioxide, epoxy resin, polyimide, or a combination of one or more of the above materials.

In one embodiment, the integrated circuit unit includes a circuit substrate having a transmission via passing through the circuit substrate, one opening of the transmission via corresponds to the light-emitting element and another opening of the transmission via corresponds to the cavity, the optical coupling structure passes through the transmission via and accommodated in the cavity.

In one embodiment, the optical coupling structure further includes a light-guiding element passing through the transmission via and accommodated in the cavity.

In one embodiment, the substrate structure comprises a plurality of the waveguide layers and a plurality of optical turning coupling ports; the waveguide layers are stacked along a direction perpendicular to the surface of the substrate structure, and one or more of the waveguide layers includes a plurality of waveguides arranged along a first direction and another one or more of the waveguide layers includes a plurality of waveguides arranged along a second direction; the optical turning coupling ports are arranged corresponding to the waveguides.

In one embodiment, a plurality of intersections are defined at positions where projections of the waveguides arranged in the first direction along the direction perpendicular to the surface and projections of the waveguides arranged in the second direction along the direction perpendicular to the surface are overlapped, and the optical turning coupling ports are arranged corresponding to the intersections.

Accordingly, the semiconductor device in this invention includes a substrate structure having a waveguide layer, a cavity arranged in the substrate structure, an integrated circuit unit having a photonic integrated circuit, and an optical coupling structure arranged in the cavity. An optoelectronic element or a light-emitting element of the photonic integrated circuit are arranged corresponding to the cavity, or arranged in the cavity. An optical path are formed between the optoelectronic element and the waveguide layer, or between the light-emitting element and the waveguide layer, and a direction of the optical path can be changed by the optical coupling structure. This invention significantly reduces the length of the optical path which can reduce signal loss of the optical signal, minimizes the semiconductor structure, and maintains the stability of optical coupling.

### BRIEF DESCRIPTION OF THE DRAWINGS

FIG. 1A is a schematic diagram of one embodiment of this invention;

FIG. 1B is a partial enlargement diagram of FIG. 1A;

FIG. 1C is a schematic diagram of another embodiment of this invention;

FIG. 2 to FIG. 4 are schematic diagrams of semiconductor devices with different types of optical coupling structures;

FIG. 5 is a schematic diagram of one embodiment of this invention;

FIG. 6 and FIG. 7 are schematic diagrams of semiconductor devices with different types of integrate circuit units;

FIG. 8A and FIG. 8B are schematic diagrams of two embodiments of this invention;

FIG. 9A and FIG. 9B are schematic diagrams of one semiconductor device with an optoelectronic elements array and multiple layers of waveguide layers; and

FIG. 10A and FIG. 10B are schematic diagrams of another semiconductor device with an optoelectronic elements array and multiple layers of waveguide layers.

### DETAILED DESCRIPTION OF THE DISCLOSURE

The foregoing is merely illustrative and not intended to limit the disclosure. In addition to the illustrative embodiments, examples, and features described above, other embodiments, examples, and features of the disclosure can be clearly understood by referring to the drawings and the following detailed description.

The following description will refer to relevant drawings to explain the stacked substrate according to the preferred embodiments of this invention, wherein the same elements will be described using the same reference symbols.

The advantages, features, and implementation methods of this disclosure will be clearly explained in the following embodiments with reference to the drawings. However, this disclosure may be embodied in various forms and should not be construed as being limited to the embodiments described herein. Rather, these embodiments are provided to make this specification thorough and complete, and to fully convey the scope of the disclosure to those skilled in the art. The scope of this disclosure should be defined only by the appended claims. Therefore, well-known components, operations, and techniques are not described in detail in the embodiments to avoid obscuring the technical features of the disclosure. Throughout the specification, identical or similar elements are denoted by identical or similar reference symbols. When an element is referred to as being "connected" to another element, it may be "directly or indirectly mechanically connected" to, or "electrically connected" to the other element, and one or more intervening elements may be present therebetween. It is to be understood that in this specification, the terms "include" or "comprise" specify the stated features, integers, steps, operations, elements and/or components, but do not preclude the presence or addition of one or more other features, integers, steps, operations, elements and/or components, or any combination thereof. The term "and/or" or “or/and” indicates the possibility of intersection or union of one or more other features, integers, steps, operations, elements and components, or any combination thereof. Unless otherwise defined, all terms used in this specification (including technical and scientific terms) have the same meanings as commonly understood by those skilled in the art to which this disclosure pertains. Further, terms, including those defined in commonly used dictionaries, should be interpreted as having meanings consistent with their meaning in the context of the relevant art and will not be interpreted in an idealized or overly rigorous sense unless explicitly defined herein.

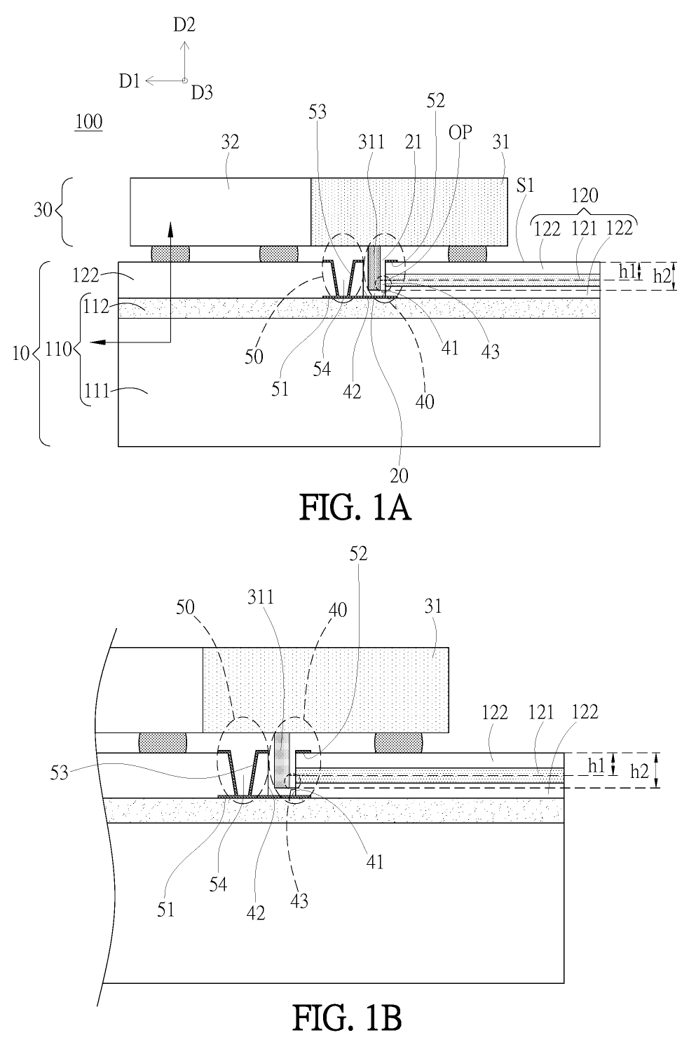

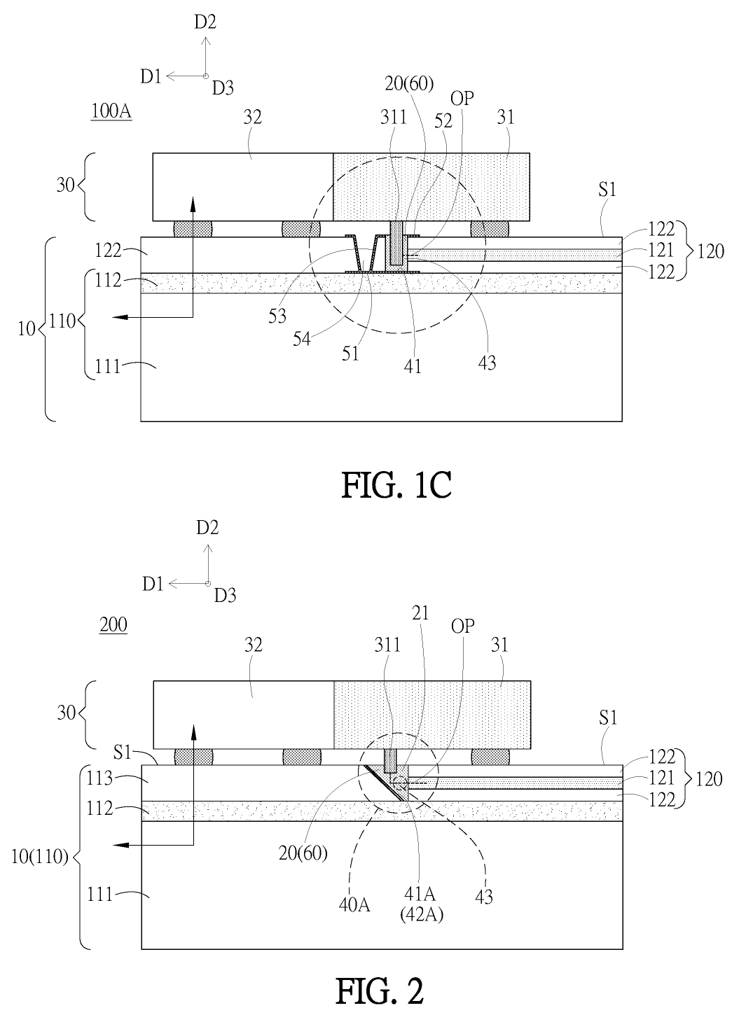

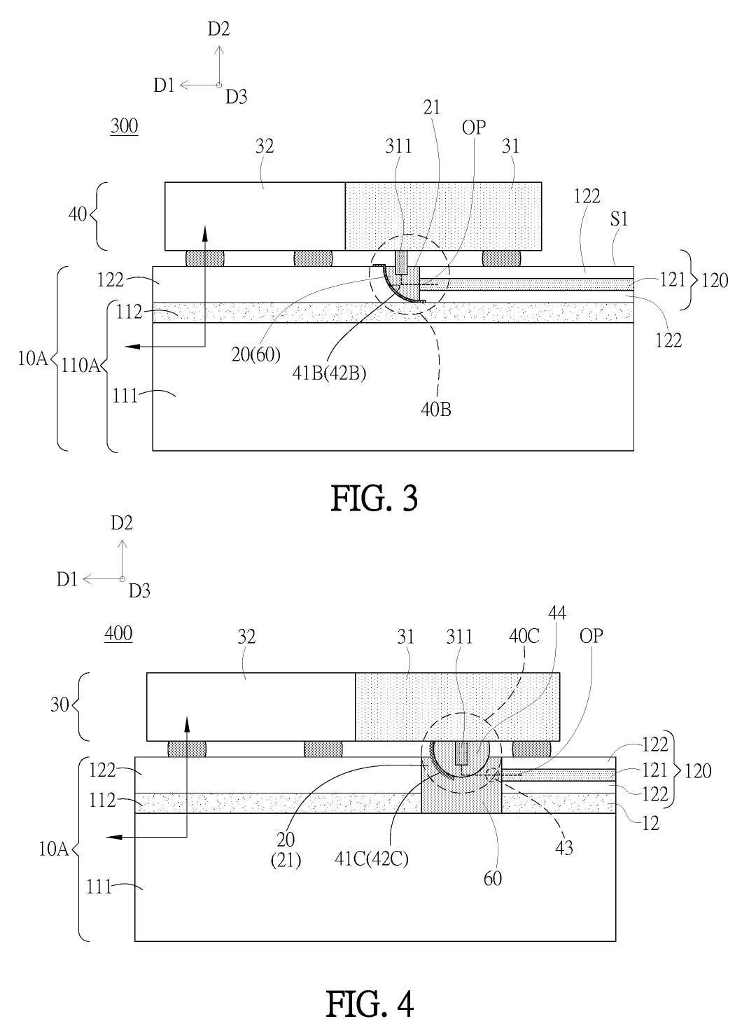

Referring to FIG. 1, which shows an embodiment of this invention. The semiconductor device 100 includes a substrate structure 10, a cavity 20, an integrated circuit unit 30, an optical path OP, and an optical coupling structure 40. The substrate structure 10 includes a base layer 110 and a waveguide layer 120 arranged on the base layer 110. The substrate structure 10 defines a surface S1, which may be a surface formed in the middle portion of the substrate structure 10 or may be an upper surface of the overall substrate structure 110. Further, one or more electrical layers can be arranged on the surface S1 of the substrate structure 10 and/or another surface opposite to the surface S1 (not shown in the figure), and the substrate structure 10 can be further provided with one or more conductive components therein (not shown in the figure), ex. conductive via(s), to perform electrical connection such as electrical connecting the substrate structure 10 with the integrated circuit unit 30. The cavity 20 is provided within the substrate structure 10 and communicated with the waveguide layer 120, and the cavity 20 defines an opening 21 on the surface S1 of the substrate structure 10. The integrated circuit unit 30 is arranged above the surface S1. Here, the term "above" refers to being on the surface S1 or over the surface S1. The integrated circuit unit 30 includes a photonic integrated circuit (PIC) 31, which corresponds to and faces to the opening 21. More specifically, the photonic integrated circuit 31 includes an optoelectronic element, the optoelectronic element is a light-emitting element 311 in this embodiment. The light-emitting element 311 is arranged corresponding to the cavity 20, ex. inserted into the cavity 20, for emitting optical signal(s). The optical path OP is formed between the light-emitting element 311 and the waveguide layer 120. In some embodiments, the integrated circuit unit 30 further includes an electronic integrated circuit (EIC) 32. The electronic integrated circuit 32 and the photonic integrated circuit 31 can be independent components, or can be integrated into one component.

The optoelectronic element referred in this invention is used for converting electronic signals into optical signals (or converting optical signals into electronic signals), which can include light-emitting elements, light detecting elements, or other elements with similar functions. In some cases, the optoelectronic element itself do not comprise circuitry for driving, amplifying, processing, or managing electrical signals. In other words, the optoelectronic element is different from traditional optical transceiver modules and do not require the integration of drivers, amplifiers, digital signal processors, or communication protocol circuitry.

The optical coupling structure 40 is arranged in the cavity 20 for steering the direction of the optical path OP. The optical coupling structure 40 includes a continuous surface 41, a light-reflective layer 42 and a transparent window 43. The light-reflective layer 42 is arranged on at least a partial of the continuous surface 41, and the transparent window 43 corresponding to the waveguide layer 120. The continuous surface 41 and the light-reflective layer 42 are configured to guide the optical path OP from a first direction to a second direction, which includes but not limited to guide the optical path OP from a horizontal direction D1 which is parallel to of the waveguide layer 120 to a vertical direction D2 toward the photonic integrated circuit 31. In addition, the waveguide layer 120 can further include one or more core layers 31. Referring to FIG. 1B, a distance between the opening 21 of the cavity 20 and the core layer 121 of the waveguide layer 120 is defines as a light-receiving depth h1; and a distance between the opening 21 of the cavity 20 and a position corresponds to the free end of the light-emitting element 311 in the cavity 20 is defines as an insertion depth h2; the light-receiving depth h1 is greater than the insertion depth h1. In some embodiments, the optical coupling structure 40 can be an independent component or can be configured to adhere to the cavity 20.

Referring to FIG. 1A and FIG. 1B, in some embodiments, the semiconductor device 100 further includes a metal reflective structure 50 surrounding the optical coupling structure 40. The metal reflective structure 50 includes at least a first metal reflective surface 51 on a side opposite the opening 21, and the light-reflective layer 42 can be the first metal reflective surface 51 or a dielectric reflective layer. The metal reflective structure 50 further includes a second metal reflective surface 52 arranged on the surface S1, which can be parallel to the first metal reflective surface 51. The metal reflective structure 50 can further include a third metal reflective surface 53 on one side of the substrate structure 10 along a direction perpendicular to the substrate structure 10, and the third metal reflective surface 53 connects to the first metal reflective surface 51, thereby forming a semi-enclosed reflective space. The metal reflective structure 50 further includes a groove 54. An axis of the groove 54 parallel to an axis of the cavity 20, and the third metal reflective surface 53 can be arranged on a lateral wall of the groove 54. Furthermore, other lateral walls of the groove 54 may also be provided with other metal reflective surfaces. These structures can be referred to FIG. 1, but are not limited to the application in FIG. 1. Referring to FIG. 1C, the semiconductive device 100A has a similar structure to the semiconductive device 100 in FIG. 1A, and the major difference therebetween is the cavity 20 of the semiconductive device 100A is filled with a first filling material 60. The first filling material 60 can include crystalline or amorphous silicon dioxide (SiO₂), epoxy resin, polyimide, or a combination of one or more of the above materials. In addition, the waveguide layers 120 in FIG. 1A to FIG. 1C cover most of the surface S1 of the substrate structure 10, and the waveguide layer 120 comprises a core layer 121 and at least one cladding layer 122. In this embodiment, the waveguide layer 121 comprises a core layer 121 and two cladding layers 122 respectively arranged at above and a below the core layer 121.

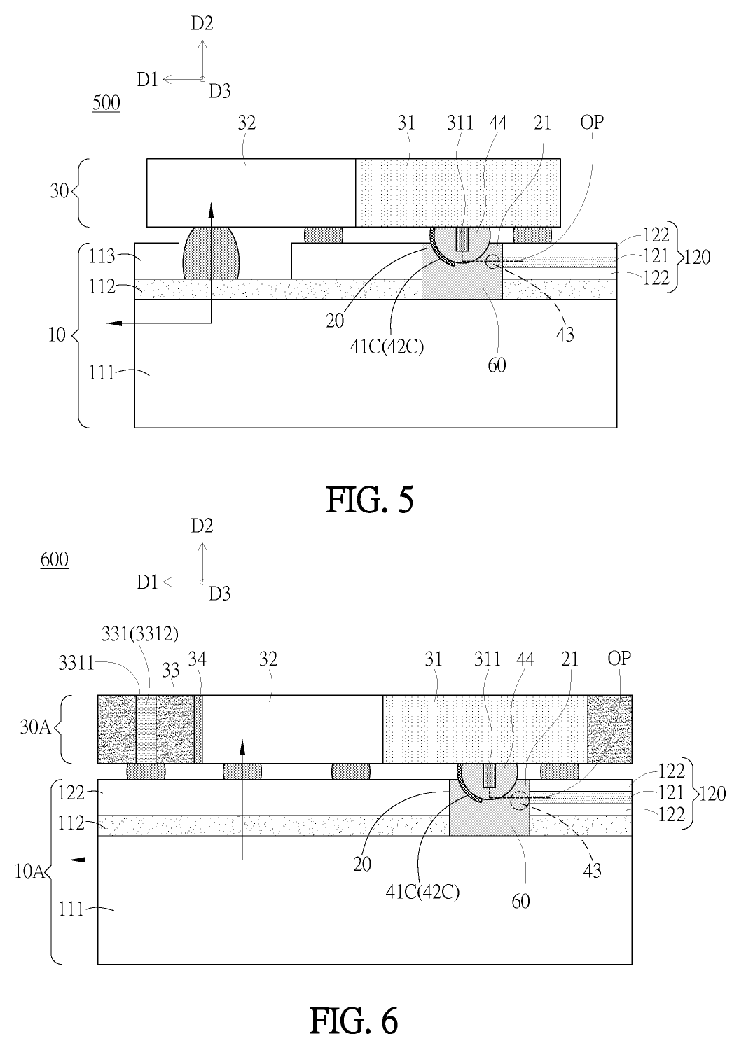

In some embodiments, the base layer 110 may include one or more base materials, as shown in FIG. 2, the substrate structure 10 of the semiconductor device 200 comprises a plurality layers of the base materials, such as the rigid layer 111 and the two resilient layers 112, 113 in which the resilient layer 112 is arranged between the rigid layer 111 and the resilient layers 113. In this embodiment, the outward-facing surface of the resilient layers 113 can be considered as a partial of the surface S1 of the substrate structure 10. In addition, the electronic integrated circuit 32 of the semiconductor device 200 is arranged on the resilient layers 112. The rigid layer 11may include, but is not limited to, materials such as glass, ceramics, silicon, silicon dioxide, FR4(Flame Retardant 4), and BT (Bismaleimide Triazine Resin Board). The resilient layer 112, 113 may include, but is not limited to, polyimide, polyethylene naphthalate (PEN), liquid crystal polymer (LCP), polycarbonate (PC), or combinations thereof. In the embodiment of FIG. 2, the waveguide layer 120 is arranged in the base layer 110 and on the resilient layer 112; and the waveguide layer 120 is flush with a surface of the other resilient layer 113. In other word, the outer surface of the waveguide layer 120 and the outer surface of the resilient layer 113 together form the surface S1 of the substrate structure 10. In addition, the cavity 20 of the semiconductor device 200 comprises an inclined plane, and this inclined plane forms the continuous surface 41A of the optical coupling structure 40A, and at least a partial or all of the inclined surface forms the light-reflective layer 42A.

The waveguide layer 120 may include a polymer waveguide layer or a silicon waveguide layer, especially the core layer 121 may include a polymer waveguide layer or a silicon waveguide layer. In some embodiments, the waveguide layer 120 can be an optical fiber with the same functional; more specifically, the waveguide layer in a broader sense includes optical fiber.

Referring to FIG. 3, the base layer 110A of the substrate structure 10A in the semiconductor device 300 is a multi-layered structure and at least comprises a rigid layer 111 and a resilient layer 112, and the waveguide 120 of the substrate structure 10A is arranged on the resilient layer 112. The waveguide layer 120 comprises a core layer 121 and at least one cladding layer 122, and the cladding layer 122 arranged on the resilient layer 112 along a direction parallel to the surface S1 of the substrate structure 10A. The core layer 121 is sandwiched between two cladding layers 122. In this embodiment, the core layer 121 is arranged at a partial of the resilient layer 112. In FIG. 3, the continuous surface 41B of the optical coupling structure 40B in the semiconductor device 300 is a concave surface, and the light-reflective layer 42B is arranged on at least a partial of the concave surface.

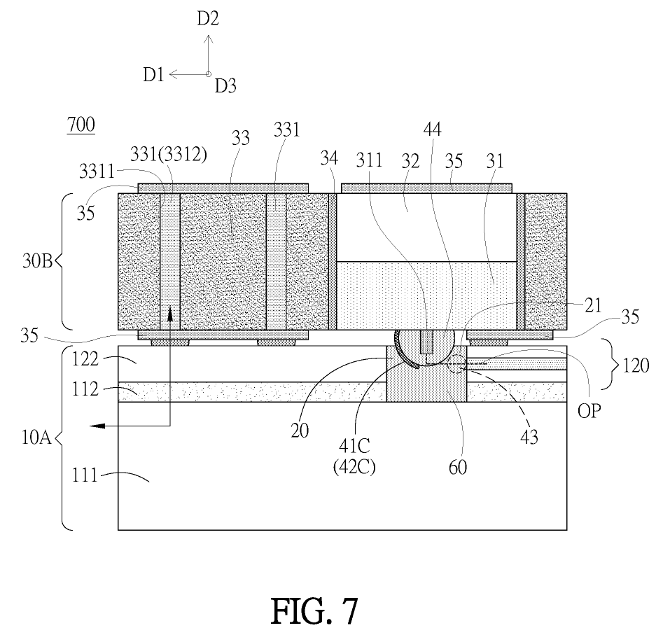

Referring to FIG. 4, the whole structure of the semiconductor device 400 is similar to the semiconductor device 300 in FIG. 3, and the major difference therebetween is the optical coupling structure 40C in the semiconductor device 400 is an independent structure and connected to the photonic integrated circuit 31. The optical coupling structure 40C is arranged at one side of the integrated circuit unit 30 facing to the substrate structure 10A and is close to the light-emitting element 311 of the photonic integrated circuit 31. Further, the optical coupling structure 40C includes a light-guiding element 44 which is arranged around the light-emitting element 311 in this embodiment, but is not limited thereto. The continuous surface 41C of the optical coupling structure 40C is formed by an outer surface of the light-guiding element 44, and the light-reflective layer 42C can be arranged on the outer surface of the light-guiding element 44. The light-guiding element 44 can include the filling material or a material having a similar character, which includes but not limited to crystalline or amorphous silicon dioxide (SiO₂), epoxy resin, polyimide, or a combination of one or more of the above materials. The light-guiding element 44 can be a light-guiding pillar, or an optical fiber structure, but is not limited. The most portion of the optical coupling structure 40C is accommodated in the cavity 20, and a first filling material 60 can be filled in the cavity 20. The first filling material 60 forms a concave surface (ex. a spherical concave surface) toward to the opening 21 of the cavity 20 and covers on a partial of the light-guiding element 44. The structure of the semiconductor device 500 in FIG. 5 is similar to FIG. 4, but the photonic integrated circuit 31 and the electronic integrated circuit 32 of the semiconductor device 400 in FIG. 4 connect to the cladding layer 122 of the waveguide layer 120 of the substrate structure 10A. However, in FIG. 5, one electrode of the electronic integrated circuit 32 connects to the resilient layer 112 of the substrate structure 10.

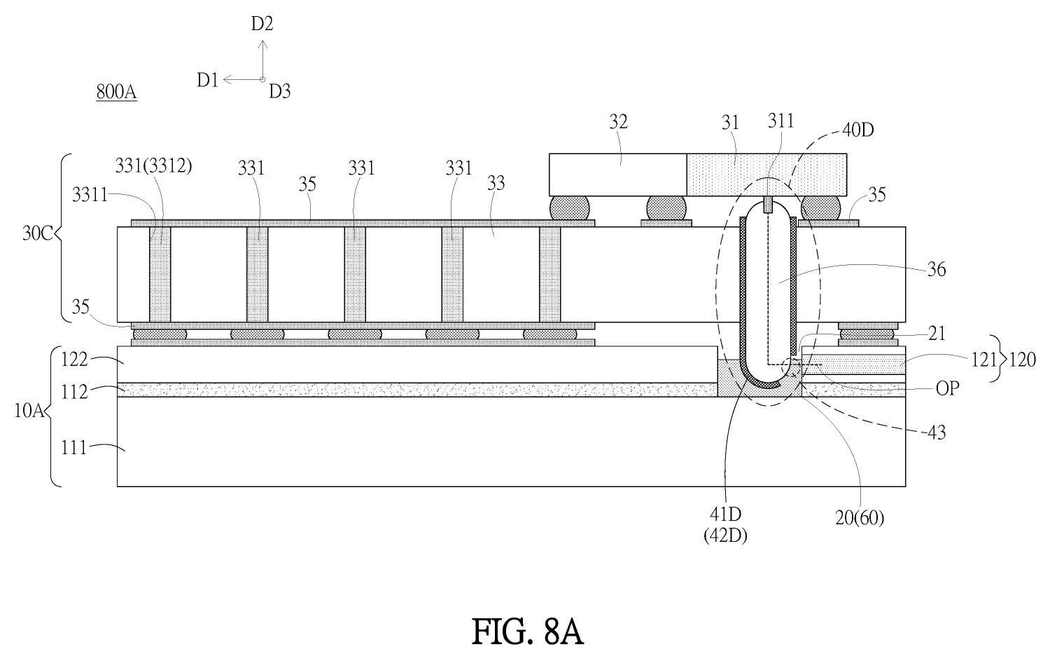

In some embodiments, the integrated circuit unit 30 further includes a circuit substrate 33, and the photonic integrated circuit 31or/and the electronic integrated circuit 32 is arranged on or in the circuit substrate 33. Referring to FIG. 6, the integrated circuit unit 30A of the semiconductor device 600 includes a photonic integrated circuit 31, an electronic integrated circuit 32, and a circuit substrate 33. The photonic integrated circuit 31 and the electronic integrated circuit 32 are arranged within the circuit substrate 33 in a co-planner manner. A filler material 34 can be filled between any two of the circuit substrate 33, the photonic integrated circuit 31, and the electronic integrated circuit 32. Furthermore, the circuit substrate 33 is provided with one or more conductive components 331, the conductive component 331 includes a conductive via 3311 passing through the circuit substrate 33 and conductive material 3312 in the conductive via 3311. Further, the electrical layers (not shown in the figure) can be arranged above and below the integrated circuit unit 30A respectively.

In some embodiments, the photonic integrated circuit 31 and the electronic integrated circuit 32 are arranged in a vertical manner. As shown in FIG. 7, the electronic integrated circuit 32 of the integrated circuit unit 30B in the semiconductor device 700 is arranged on or above the photonic integrated circuit 31, and both of the photonic integrated circuit 31 and the electronic integrated circuit 32 are arranged within the circuit substrate 33. The filler material 34 is further arranged between the circuit substrate 33, the photonic integrated circuit 31 and the electronic integrated circuit 32. Moreover, the circuit substrate 33 has one or more conductive components 331, which includes a conductive via 3311 passing through the circuit substrate 33 and a conductive material 3312 in the conductive via 3311. In addition, the integrated circuit unit 30B is provided with electrical layers 35 which are respectively arranged above and below the integrated circuit unit 30B.

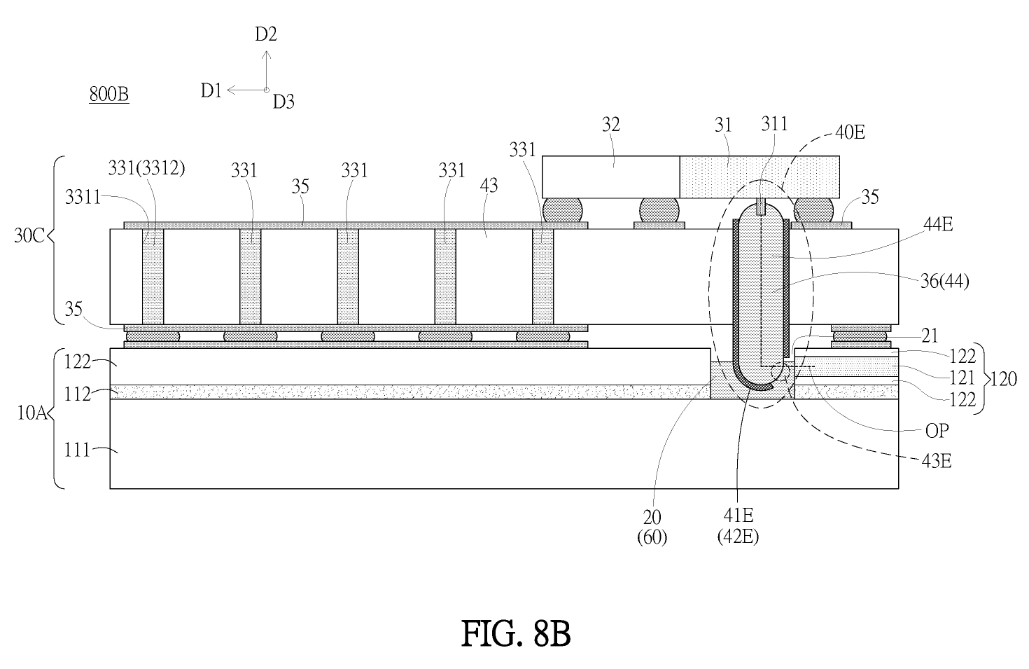

In some other embodiments, as shown in FIG. 8A and FIG. 8B, the photonic integrated circuit 31 and the electronic integrated circuit 32 of the integrated circuit unit 30C in the semiconductor devices 800A, 800B are arranged on the circuit substrate 33. Additionally, the circuit substrate 33 is provided with one or more conductive components 331, which includes a conductive via 3311 and a conductive material 3312 in the conductive via 3311. The integrated circuit unit 30C is provided with electrical layers 35 which are respectively arranged above and below the integrated circuit unit 30C. Further, the circuit substrate 33 of the integrated circuit 30C include a transmission via 36 corresponding to the light emitting element 311, and the transmission via 36 passes through the circuit substrate 33 of the integrated circuit 30C. One opening of the transmission via 36 corresponds to the light-emitting element 311, and the other opening thereof corresponds to the cavity 20 in the substrate structure 10A. In FIG. 8A, the optical coupling structure 40D passes through the transmission via 36 and accommodated in the cavity (the first filling material 60 is filled in the cavity 20), and the optical coupling structure 40D does not include the light guiding element 44; the light-reflective layer 42D and the light-transmission window 43D correspond to the waveguide layer 120, especially the core layer 121 of the waveguide layer 120. The light-transmission window 43D of the optical coupling structure 40D is surrounded by the light-reflective layer 42D, in other words, the light-transmission window 43D is defined by the light-reflective layer 42D. In FIG. 8B, the optical coupling structure 40E includes a light guiding element 44E which passes through the transmission via 36 of the circuit substrate 33 and is accommodated in the cavity 20 (the first filling material 60 is filled in the cavity 20). The continuous surface 41E and the light-reflective layer 42E are arranged on the outer surface of the light guiding element 44E. Similar to FIG. 8A, the light-transmission window 43E is surrounded by the light-reflective layer 42E, in other words, the light-transmission window 43E is defined by the light-reflective layer 42E. In FIG. 8B, the light-reflective layer 42E is arranged between the light guiding element 44E and the first filling material 60.

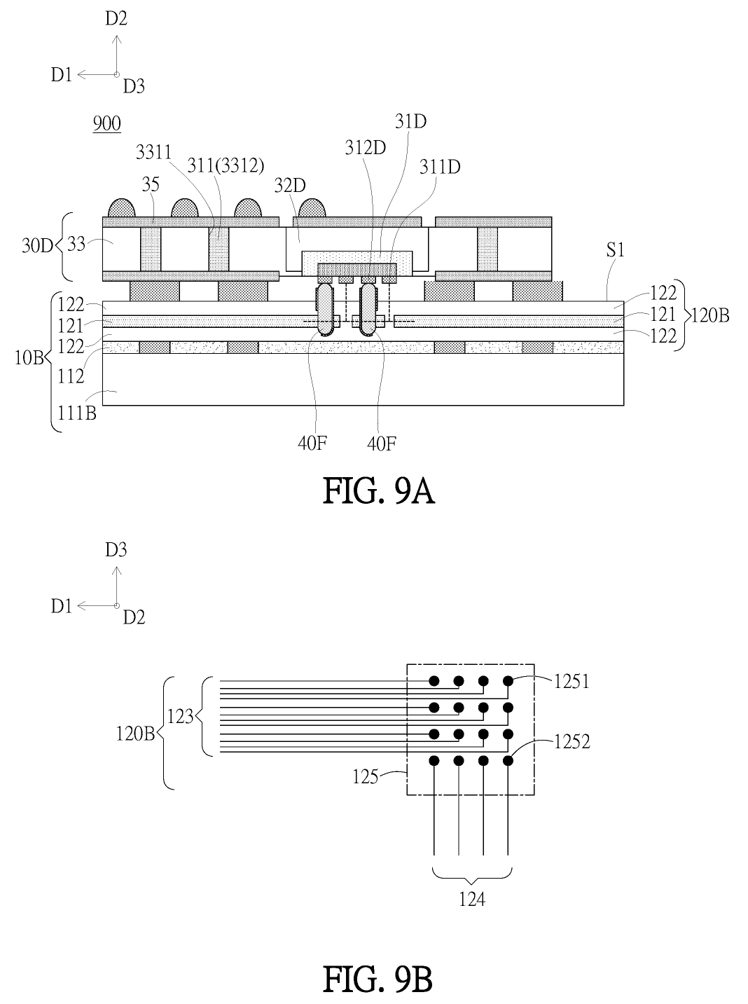

Referring to FIG. 9A and FIG. 9B, in the integrated circuit unit 30D of the semiconductor device 900, the photonic integrated circuit 31D and the electronic integrated circuit 32D are arranged vertically within the substrate 33. A filler material (not shown in the figure) can be arranged between the substrate 33 and the photonic integrated circuit 31D and the electronic integrated circuit 32D. Additionally, the circuit substrate 33 has one or more conductive components 331. The conductive component 331 includes a conductive via 3311 passing through the circuit substrate 33 and a conductive material 3312 in the conductive via 3311. In addition, the integrated circuit 30D is provided with the electrical layers 35above and below the circuit substrate 33 thereof. The photonic integrated circuit 31D includes multiple light-emitting elements 311D witch are arranged in an array. In this embodiment, the photonic integrated circuit 31D may further include multiple photosensitive elements 312B which are also arranged in an array for receiving optical signals. The light-emitting elements 311D include, for example, light-emitting diodes, organic light-emitting diodes or optical fibers. The photosensitive elements 312Dare arranged corresponding to the multiple optical coupling structures 40F, the specific structure can be referred to FIG. 8B. The photonic integrated circuit 31D may further include light-guiding columns (not shown in the figure) corresponding to the light-emitting elements 311D. The substrate structure 10B of the semiconductor device 900 includes a rigid layer 111B, a resilient layer 112 and one or more waveguide layers 120B on the resilient layer 112. In the embodiments which the substrate structure 10B comprises multiple waveguide layers 120B, these waveguide layers 120B are stacked along a direction D2 perpendicular to the surface S1 of the substrate structure 10B. Each of the waveguide layers 120B includes waveguides, and the waveguides can be arranged in a same direction or in different directions, which is not limited. Referring to FIG. 9B, one waveguide layer 120B includes M waveguides 123along the direction D1, and another waveguide layer 120B includes N waveguides 124 along a direction D3. Additionally, the waveguide layer 120B defines an optical coupling region 125 which includes multiple optical turning coupling ports 1251, 1251. The optical turning coupling ports 1251, 1251 are arranged on the waveguides 123, 124. In some embodiments, one or more intersections are defined at positions where projections of the waveguides 123 arranged in the direction D1 along the direction D2, and projections of the waveguides 124 arranged in the direction D3 along the vertical direction D2 are overlapped. The optical turning coupling ports 1251, 1252 are arranged corresponding to these intersections. These intersections also correspond to the light-emitting elements 311D and the photosensitive element array 312D, respectively.

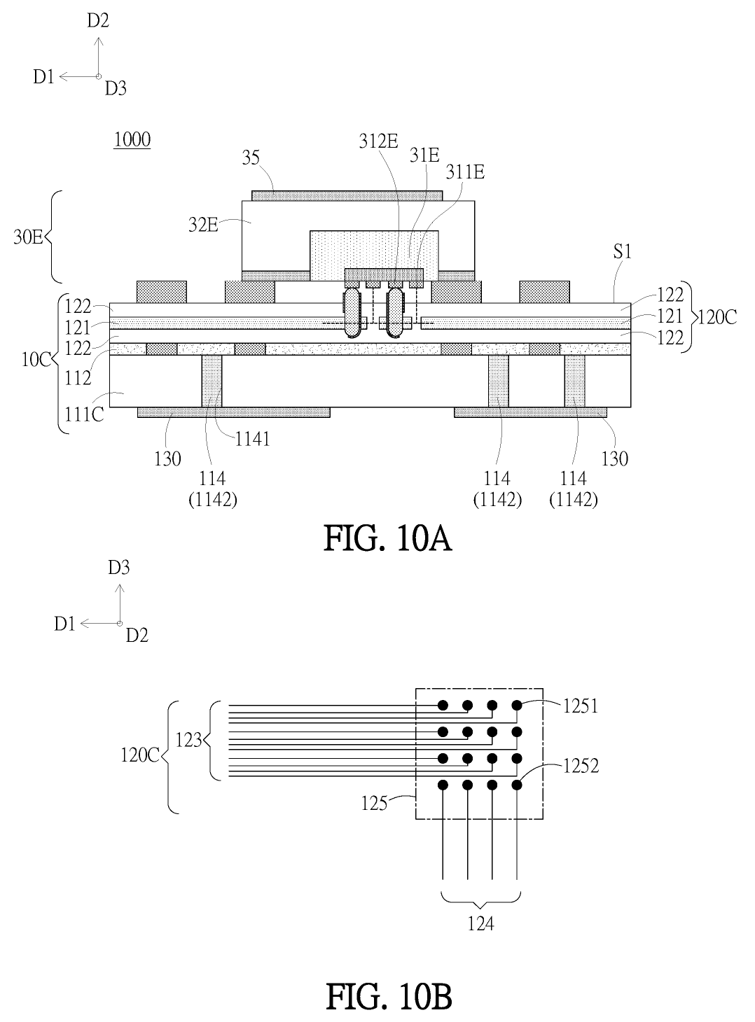

Referring to FIG. 10A and FIG. 10B, the photonic integrated circuit 31E and the electronic integrated circuit 32E of the integrated circuit unit 30E are integrated into an integrated unit in the semiconductor device 1000, but the integrated unit is not integrated into a substrate. Electrical layers 35 are arranged above and below the integrated circuit unit 30E. The photonic integrated circuit 31E is similar to the photonic integrated circuit 31D in FIG. 9A and FIG. 9B, it also comprises multiple light-emitting elements 311E and multiple photosensitive elements 312E. In FIG. 10A, the substrate structure 10C includes a rigid layer 111C, a resilient layer 112, and one or more waveguide layers 120C arranged on the resilient layer 112. Additionally, in this embodiment, the substrate structure 10C further includes multiple conductive components 114, which includes conductive via 1141 passing through the rigid layer 111C (or the substrate structure 10C) and a conductive material 1142 in the conductive via 1141, but is not limited thereto. In some embodiments, the substrate structure 10C further includes one or more electrical layers 130 arranged on another surface opposite to the surface S1; the electrical layers 130 electrically connected to the conductive components 114. In the embodiments which the substrate structure 10C comprises multiple waveguide layers 120C, the configuration of the multiple waveguide layers 120C and the waveguides 123, 124 arranged thereon are similar to those in FIG. 9A and FIG. 9B.

Accordingly, the semiconductor device in this invention includes a substrate structure having a waveguide layer, a cavity arranged in the substrate structure, an integrated circuit unit having a photonic integrated circuit, and an optical coupling structure arranged in the cavity. An optoelectronic element or a light-emitting element of the photonic integrated circuit are arranged corresponding to the cavity, or arranged in the cavity. An optical path are formed between the optoelectronic element and the waveguide layer, or between the light-emitting element and the waveguide layer, and a direction of the optical path can be changed by the optical coupling structure. This invention significantly reduces the length of the optical path which can reduce signal loss of the optical signal, minimizes the semiconductor structure, and maintains the stability of optical coupling.

Based on the above description, it should be understood that various embodiments of the disclosure have been described in the specification for illustrative purposes, and various modifications can be made without departing from the scope and spirit of the disclosure. Therefore, the various embodiments of the disclosure are not intended to limit the true scope and spirit of the invention.

The above descriptions are exemplary rather than restrictive. Any equivalent modifications or changes made without departing from the spirit and scope of this invention should be included in the appended patent claims.

What is claimed is:

1. A semiconductor device, comprising:
a substrate structure defining a surface and including a base layer and a waveguide layer stacked on the base layer;
a cavity arranged in the substrate structure, communicated with the waveguide layer, and includes an opening on the surface of the substrate structure;
an integrated circuit unit arranged above the surface of the substrate structure, wherein the integrated circuit unit includes a photonic integrated circuit and the photonic integrated circuit has an optoelectronic element corresponding to the cavity;
an optical path formed between the optoelectronic element and the waveguide layer; and
an optical coupling structure configured within the cavity for steering the optical path; wherein the optical coupling structure includes a continuous surface, an optical reflective layer on at least a portion of the continuous surface, and a light-transmitting window corresponding to the waveguide layer; wherein the continuous surface and the light reflective layer are configured to guide the optical path from a first direction to a second direction.

2. A semiconductor device, comprising:
a substrate structure defining a surface and including a base layer and a waveguide layer stacked on the base layer;
a cavity arranged in the substrate structure, communicated with the waveguide layer, and includes an opening on the surface of the substrate structure;
an integrated circuit unit arranged above the surface of the substrate structure, wherein the integrated circuit unit includes a photonic integrated circuit and the photonic integrated circuit has a light-emitting element corresponding to the cavity;
an optical path formed between the light-emitting element and the waveguide layer; and
an optical coupling structure configured within the cavity for steering the optical path; wherein the optical coupling structure includes a continuous surface, an optical reflective layer on at least a portion of the continuous surface, and a light-transmitting window corresponding to the waveguide layer; wherein the continuous surface and the light reflective layer are configured to guide the optical path from a first direction to a second direction different from the first direction.

3. The semiconductor device according to claim 2, wherein the light-emitting element is arranged in the cavity.

4. The semiconductor device according to claim 2, wherein the substrate structure defines an electrical layer on the surface.

5. The semiconductor device according to claim 2, wherein the waveguide layer is arranged within the base layer and a surface thereof facing to the integrated circuit unit is flush with a surface of the base layer facing to the integrated circuit unit.

6. The semiconductor device according to claim 2, wherein the base layer includes a rigid layer and a resilient layer stacked over the rigid layer.

7. The semiconductor device according to claim 2, wherein the waveguide layer includes a polymer waveguide layer or a silicon waveguide layer.

8. The semiconductor device according to claim 2, wherein the integrated circuit unit further includes an electronic integrated circuit.

9. The semiconductor device according to claim 8, wherein the electronic integrated circuit and the photonic integrated circuit are individual from one another.

10. The semiconductor device according to claim 2, wherein the integrated circuit unit further includes a circuit substrate and the photonic integrated circuit is arranged on the circuit substrate.

11. The semiconductor device according to claim 8, wherein the integrated circuit unit further includes a circuit substrate, and the photonic integrated circuit and the electronic integrated circuit are arranged on the circuit substrate.

12. The semiconductor device as described in claim 2, wherein the optical coupling structure is a discrete component.

13. The semiconductor device according to claim 2, wherein the cavity defines a plane with an inclined angle or a concave surface with an inclined angle, and the plane or the concave surface forms the continuous surface.

14. The semiconductor device according to claim 2, wherein the optical coupling structure defines a concave surface toward the opening of the cavity, and the concave surface forms the continuous surface of the optical coupling structure, the optical reflective layer of the optical coupling structure is partially arranged on the continuous surface, and the light-transmitting window is defined by the continuous surface.

15. The semiconductor device according to claim 14, further comprising a first filling material in the cavity, wherein the first filling material forms the concave surface toward the opening of the cavity.

16. The semiconductor device according to claim 15, wherein the first filling material comprises silicon dioxide, epoxy resin, polyimide, or a combination of one or more of the above materials.

17. The semiconductor device according to claim 2, wherein the integrated circuit unit further includes a circuit substrate having a transmission via passing through the circuit substrate, wherein one opening of the transmission via corresponds to the light-emitting element and another opening of the transmission via corresponds to the cavity, wherein the optical coupling structure passes through the transmission via and accommodated in the cavity.

18. The semiconductor device according to claim 17, further including a light-guiding element passing through the transmission via and accommodated in the cavity

19. The semiconductor device according to claim 2, wherein the substrate structure further includes a plurality of waveguide layers stacked along a direction perpendicular to the surface of the substrate structure and a plurality of optical turning coupling ports, wherein one or more of the waveguide layers includes a plurality of waveguides arranged along a first direction and another one or more of the waveguide layers includes a plurality of waveguides arranged along a second direction and the optical turning coupling ports are arranged corresponding to the waveguides.

20. The semiconductor device according to claim 19, wherein a plurality of intersections are defined at positions where projections of the waveguides arranged in the first direction along the direction perpendicular to the surface and projections of the waveguides arranged in the second direction along the direction perpendicular to the surface are overlapped, and the optical turning coupling ports are arranged corresponding to the intersections.
